(19) United States
(12) Patent Application Publication
(10) Pub. No.: US 2024/0249049 A1
(43) Pub. Date: Jul. 25, 2024

(54) GENERATION METHOD FOR ENERGY STORAGE DEVICE MODEL, GENERATION DEVICE FOR ENERGY STORAGE DEVICE MODEL, AND PROGRAM

(71) Applicant: GS Yuasa International Ltd., Kyoto-shi, Kyoto (JP)

(72) Inventors: Shoko HIRANO, Kyoto (JP); Shigeki YAMATE, Kyoto (JP); Naoto NISHIMURA, Kyoto (JP)

(21) Appl. No.: 18/561,362

(22) PCT Filed: Apr. 11, 2022
(86) PCT No.: PCT/JP2022/017473

§ 371 Date: Nov. 16, 2023

(30) Foreign Application Priority Data
May 20, 2021 (JP) 2021-085570

(51) Int. Cl. G06F 30/32; G01R 31/367; G01R 31/3842

(52) U.S. Cl. CPC G06F 30/32; G01R 31/367; G01R 31/3842

(57) ABSTRACT

In a generation method for an energy storage device model, in order to simulate a transient actual voltage behavior when an actual current flows in an actual energy storage device for a predetermined period, a parameter in an energy storage device model is adjusted such that a transient model voltage behavior, which is a behavior when a model current equivalent to the actual current flows in the energy storage device model for a predetermined period, approaches the actual voltage behavior. In the generation method for an energy storage device model, in the adjustment, the parameter is changed so as to simulate a state transition of the energy storage device model accompanied by the flow of the model current.

### TECHNICAL FIELD

The present invention relates to a generation method for an energy storage device model, a generation device for an energy storage device model, and a program.

### BACKGROUND ART

As one of methods for estimating a behavior of a secondary battery, a method for estimating the behavior of the secondary battery such as SOC (State of Charge) by applying a Kalman filter to an equivalent circuit model, which represents the secondary battery by an electric circuit, is known (see, for example, Patent Document 1).

### PRIOR ART DOCUMENT

### Patent Document

Patent Document 1: JP-A-2016-065828

### SUMMARY OF THE INVENTION

### Problems to be Solved by the Invention

Concerning an equivalent circuit model (ECM) that simulates current-voltage characteristics of an energy storage device such as a secondary battery, consideration of a state transition of the energy storage device accompanied by its operation, e.g., an SOC change, a temperature change, and deterioration of the energy storage device, has not been sufficiently studied yet.

An object of the present disclosure is to provide a generation method for an energy storage device model, a generation device for an energy storage device model, and a program capable of appropriately simulating a behavior of an energy storage device.

### Means for Solving the Problems

In a generation method for an energy storage device model according to an aspect of the present disclosure, in order to simulate a transient actual voltage behavior when an actual current flows in an actual energy storage device for a predetermined period, a parameter in an energy storage device model is adjusted such that a transient model voltage behavior, which is a behavior when a model current equivalent to the actual current flows in the energy storage device model for a predetermined period, approaches the actual voltage behavior. In the generation method for an energy storage device model, in the adjustment, the parameter is changed so as to simulate a state transition of the energy storage device model accompanied by the flow of the model current.

### Advantages of the Invention

According to the present disclosure, it is possible to generate an energy storage device model that appropriately simulates a transient voltage behavior with respect to a current in an actual energy storage device.

### BRIEF DESCRIPTION OF THE DRAWINGS

FIG. 1 is a diagram showing an example of an ECM of an energy storage device.

FIG. 2 is a conceptual diagram showing an example of table data of circuit parameters.

FIG. 3 is an explanatory diagram showing a method for acquiring circuit parameters in a conventional ECM.

FIG. 4 is a graph showing a relationship between a DC resistance and an SOC.

FIG. 5 is a conceptual diagram showing an overall image of life prediction calculation of the energy storage device.

FIG. 6 is a block diagram of a generation device according to the present embodiment.

FIG. 7 is an explanatory diagram for explaining a method for acquiring circuit parameters in an energy storage device model of the present embodiment.

FIG. 8 is a flowchart showing an example of a generation processing procedure of the energy storage device model.

FIG. 9 is a graph showing a verification result of the ECM generated by the method of the present embodiment.

FIG. 10 is a graph showing a relationship between a DC internal resistance and a capacity retention ratio of a lithium ion battery.

FIG. 11 is a diagram showing an example of an ECM of an energy storage device in a second embodiment.

FIG. 12 is an explanatory diagram for explaining a method for acquiring circuit parameters in the energy storage device model of the second embodiment.

FIG. 13 is a flowchart showing an example of a generation processing procedure of the energy storage device model in the second embodiment.

FIG. 14 is a diagram showing an example of an ECM of an energy storage device in a third embodiment.

FIG. 15 is a flowchart showing an example of a generation processing procedure of the energy storage device model in the third embodiment.

FIG. 16 is an explanatory diagram for explaining a method for acquiring circuit parameters in an energy storage device model of a fourth embodiment.

FIG. 17 is a flowchart showing an example of a generation processing procedure of the energy storage device model in the fourth embodiment.

FIG. 18 is a graph showing a verification result of the ECM generated by the method of the fourth embodiment.

### MODE FOR CARRYING OUT THE INVENTION

In a generation method for an energy storage device model, in order to simulate a transient actual voltage behavior when an actual current flows in an actual energy storage device for a predetermined period, a parameter in an energy storage device model is adjusted such that a transient model voltage behavior, which is a behavior when a model current equivalent to the actual current flows in the energy storage device model for a predetermined period, approaches the actual voltage behavior. In the generation method for an energy storage device model, in the adjustment, the parameter is changed so as to simulate a state transition of the energy storage device model accompanied by the flow of the model current.

Here, the “actual energy storage device” means an energy storage device which physically exists. The “actual current” means a current flowing through the actual energy storage device, and may be a discharge current from the actual energy storage device or a charge current to the actual energy storage device. The “actual voltage behavior” means a voltage behavior in the actual energy storage device. The energy storage device model simulates a charge-discharge behavior of the energy storage device by combining a voltage source of the energy storage device and a circuit element such as a resistance and a capacitor. The energy storage device model may be an equivalent circuit model. The “parameter” may be a circuit parameter in an ECM. The “model current” may be a discharge current from the energy storage device model or a charge current to the energy storage device model. The “model voltage behavior” means a voltage behavior in the energy storage device model.

In the actual energy storage device, when the actual current (discharge current or charge current) flows for a predetermined period, a state of the energy storage device such as a state of charge (SOC) or a temperature changes. When the discharge current flows, the SOC of the energy storage device decreases, and when the charge current flows, the SOC of the energy storage device increases. However, conventionally, the state transition of the energy storage device is not considered at the time of acquiring the circuit parameter in the ECM.

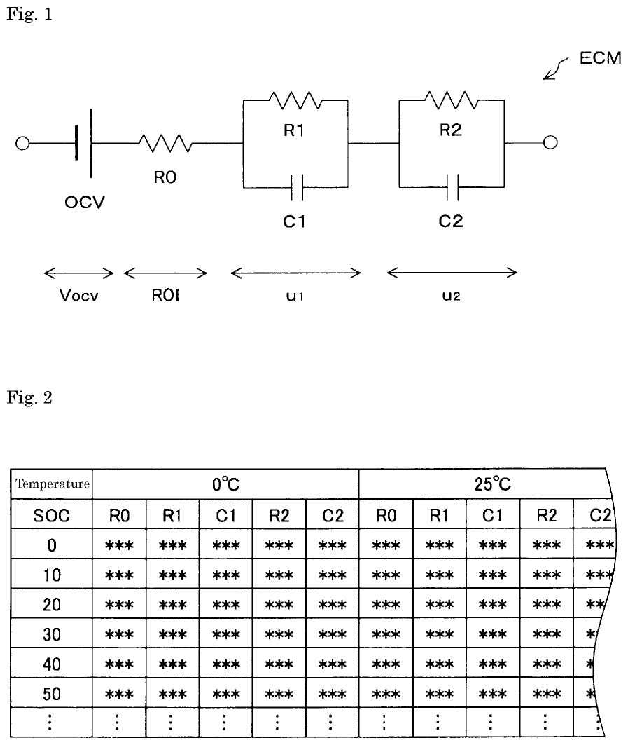

An example of a conventional method for acquiring circuit parameters in an ECM will be described. FIG. 1 is a diagram showing an example of an ECM of an energy storage device (hereinafter, also referred to as a battery). The ECM shown in FIG. 1 includes, as circuit parameters, an open circuit voltage (OCV) simulating a battery (for example, a lithium ion battery), and an R0 and two stages of RC parallel circuits (R1, C1, R2, C2) that simulates an overvoltage (polarization amount). In FIG. 1, Vocv represents an electromotive voltage of the battery OCV, R0I represents an initial ohmic resistance (less than 1 second to 1 second when calculated at intervals of 1 second), and u1 and u2 represent subsequent non-ohmic resistances (after 1 second elapses when calculated at intervals of 1 second).

The voltage behavior when a current I is input to the ECM shown in FIG. 1 can be expressed by Expressions (1) and (2) below.

$$[ Expression 1 ]$$

$${V}_{calc} = {V}_{ocv} + R 0 I + {u}_{1} + {u}_{2} \qquad ( 1 )$$

$${u}_{n ( t )} = ( 1 - \frac{Δ t}{{R}_{n} {C}_{n}} ) {u}_{n ( t - 1 )} + \frac{Δ t}{{C}_{n}} I \qquad ( 2 )$$

(in the expression, n=1, 2, . . . ,
Δt: Sampling interval, Relation of time (t)—time (t−1) holds)

Here, Vcalc is a voltage (terminal voltage), and un is a voltage change amount by an RC parallel circuit including Rn and Cn.

When simulating the current-voltage characteristics using the above-described ECM, each circuit parameter (R0, R1, C1, R2, C2) constituting the ECM is used. Each circuit parameter is set in advance based on actually measured data or the like according to the purpose of the battery to be simulated. FIG. 2 is a conceptual diagram showing an example of table data of the circuit parameters. As shown in FIG. 2, the circuit parameters are stored as, for example, two-dimensional table data of the SOC and the temperature of the battery. The two-dimensional table stores each of R0, R1, C1, R2, and C2 with respect to the SOC and the temperature at predetermined intervals.

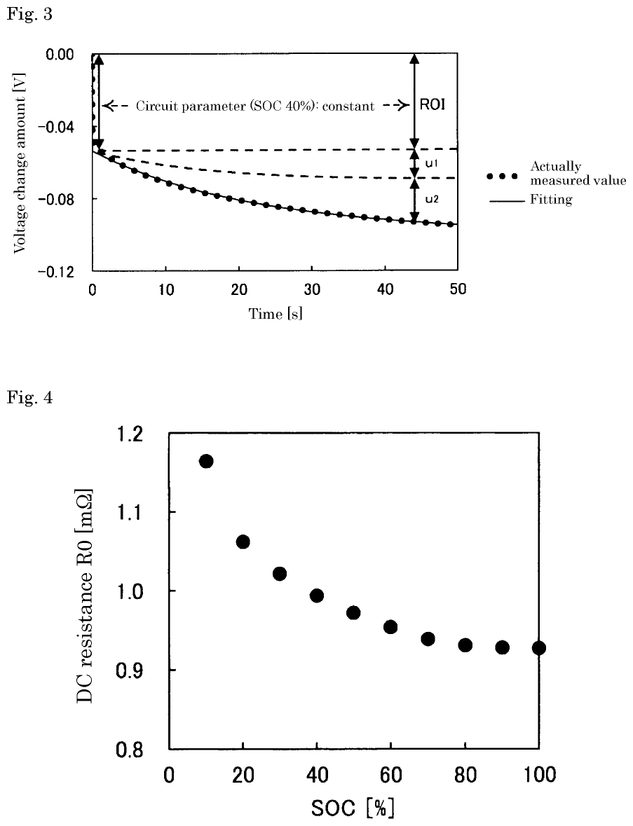

FIG. 3 is an explanatory diagram showing a method for acquiring circuit parameters in a conventional ECM. Hereinafter, as an example, an example of obtaining a circuit parameter (R0, R1, C1, R2, C2) of the ECM that simulates the transient voltage behavior of the lithium ion battery when the discharge current flows from a temperature of 0° C. and an SOC of 40% for 50 seconds will be described. The calculation interval is 1 second. The graph in FIG. 3 shows the relationship between the discharge time and the voltage change. The horizontal axis of the graph represents a time (s) from the start of discharge, and the vertical axis represents a voltage change amount ΔV (V) accompanying discharge. In FIG. 3, a dot represents a voltage change amount obtained by actual measurement, and a solid line represents a voltage change amount obtained by fitting calculation described later. The voltage change amount corresponds to the polarization voltage.

First, R0 is set by dividing the voltage drop value at 1 second obtained from the actually measured data by the energized current value. Here, it is assumed that the SOC and the temperature do not change during 50 seconds of energization, and it is assumed that the SOC and the temperature at the start of energization are constant. Next, R0 is kept constant, and the voltage behavior after 1 second elapses is obtained by fitting calculation. That is, the remaining four circuit parameters (R1, C1, R2, C2) are calculated by adjusting the voltage behavior of the ECM to approach the profile connecting the dots. In this case, the remaining four circuit parameters are also calculated as constant values similarly to R0. R1, C1, R2, and C2 thus obtained and R0 are recorded in the two-dimensional table data shown in FIG. 2. As described above, the circuit parameters corresponding to the temperature at the start of discharge and the SOC are acquired.

In the conventional method for acquiring circuit parameters described above, the state transition of the battery is not considered. By discharging at a predetermined current for 50 seconds from the SOC 40%, the circuit parameters of the SOC 40% and the temperature of 0° C. are set although the SOC of the battery decreases and the temperature also changes. That is, the circuit parameters are determined on the assumption that the SOC and the temperature do not change during energization. Furthermore, it is assumed that the internal impedance of the battery does not change when the change in SOC or temperature is small.

FIG. 4 is a graph showing a relationship between DC resistance and the SOC. In FIG. 4, the horizontal axis represents SOC (%), and the vertical axis represents DC resistance R0 (mΩ). As shown in FIG. 4, it is known that the DC resistance greatly changes according to the change in the SOC particularly in the low SOC region. In the conventional method for acquiring circuit parameters, such SOC dependency of R0 is not considered. R0 depends not only on the SOC but also on the temperature of the battery and the state of health (SOH) of the battery. Such a state transition of the battery is not considered in the conventional method for acquiring circuit parameters. When simulating the current-voltage characteristics using the ECM including the circuit parameters, there is a possibility that the calculation accuracy decreases particularly in a region where the state transition of the battery is large.

The present inventors have devised that “when a parameter is adjusted such that a transient model voltage behavior when a model current equivalent to an actual current flows in an energy storage device model for a predetermined period approaches an actual voltage behavior, the parameter is changed so as to simulate a state transition of the energy storage device model accompanying the flow of the model current”.

With such a configuration, it is possible to generate an energy storage device model that appropriately simulates a transient voltage behavior with respect to a current in an actual energy storage device. Based on this energy storage device model, an effect of efficiently designing and developing a system using the energy storage device can be expected. The energy storage device model can be used not only for design and development but also for state diagnosis and various controls of the energy storage device during operation of the energy storage device.

In the generation method for an energy storage device model, in the adjustment, the parameter at a time point between a start time point and an end time point of the predetermined period may be obtained by interpolation calculation.

According to the above configuration, by performing interpolation calculation using the parameters at the start time point and the end time point of the predetermined period, it is possible to efficiently calculate the parameters in consideration of the state transition of the energy storage device. With such a parameter, it is possible to generate an energy storage device model that accurately simulates a transient voltage behavior.

In the generation method for an energy storage device model, the energy storage device model may be an equivalent circuit model including a resistor that simulates a DC resistance component of the energy storage device, and, in the adjustment, the parameter related to the resistor may be changed.

According to the above configuration, in the adjustment of the parameter, the circuit parameter R0 related to the resistor that simulates the DC resistance component in the ECM is changed. By performing interpolation calculation on R0 at a time point within a predetermined time by using R0 corresponding to the SOC of the energy storage device at the start time point and R0 corresponding to the SOC of the energy storage device at the end time point, the SOC dependency of R0 can be reflected in the energy storage device model.

In the generation method for the energy storage device model, the parameter may be changed so as to simulate a transition of a health state and/or a temperature of the energy storage device model accompanying the flow of the model current.

According to the above configuration, since the parameter is changed so as to correspond to the health state and/or the temperature of the energy storage device, the health state and/or the temperature dependence of the parameter can be reflected in the energy storage device model. The parameter may be determined based on a resistance deterioration amount which is a function of the health state and the temperature of the energy storage device.

In the generation method for an energy storage device model, the energy storage device model may be an equivalent circuit model including a resistor that simulates a DC resistance component of the energy storage device, and an RC parallel circuit that simulates polarization characteristics of the energy storage device. In the generation method for an energy storage device model, in the adjustment, the parameter related to the resistor and the parameter related to the RC parallel circuit may be changed.

According to the above configuration, the state transition of the energy storage device can be reflected on both the DC resistance component and the RC parallel circuit in the energy storage device model. By adjusting both the parameter related to the DC resistance component included in the energy storage device model and the parameter related to the RC parallel circuit, it is possible to improve the reproduction accuracy of the voltage behavior as compared with the case of adjusting only the parameter related to the DC resistance component.

In the generation method for an energy storage device model, the energy storage device model may be an equivalent circuit model including a resistor that simulates a DC resistance component of the energy storage device, and a plurality of RC parallel circuits that simulate polarization characteristics of the energy storage device. In the generation method for an energy storage device model, in the adjustment, the parameter related to at least one RC parallel circuit among the plurality of RC parallel circuits may be changed, the RC parallel circuit being configured to express a transition of a health state and/or a temperature of the energy storage device model.

According to the above configuration, the RC parallel circuit including the parameter expressing the transition of the health state and/or the temperature of the energy storage device model is added to the energy storage device model. In order to simulate the deterioration characteristics of the polarization voltage, only the parameter related to the added RC parallel circuit is changed among the plurality of RC parallel circuits. It is not necessary to adjust parameters related to other RC parallel circuits for the purpose of simulating deterioration characteristics of the polarization voltage, and it is possible to generate an energy storage device model that reduces an arithmetic load.

In the generation method for an energy storage device model, in the adjustment, the parameter may be changed based on a heat generation amount of the energy storage device model.

According to the above configuration, since the parameter is changed so as to correspond to the heat generation amount of the energy storage device model, the deterioration polarization amount that changes according to the heat generation amount of the energy storage device model can be reflected in the energy storage device model.

A generation device for an energy storage device model includes an adjustment unit that adjusts, so as to simulate a transient actual voltage behavior when an actual current flows in an actual energy storage device for a predetermined period, a parameter in an energy storage device model such that a transient model voltage behavior, which is a behavior when a model current equivalent to the actual current flows in the energy storage device model for a predetermined period, approaches the actual voltage behavior. In the energy storage device model generation device, the adjustment unit changes, in the adjustment, the parameter so as to simulate a state transition of the energy storage device model accompanied by the flow of the model current.

A program causes a computer to execute the processing of: adjusting, so as to simulate a transient actual voltage behavior when an actual current flows in an actual energy storage device for a predetermined period, a parameter in an energy storage device model such that a transient model voltage behavior, which is a behavior when a model current equivalent to the actual current flows in the energy storage device model for a predetermined period, approaches the actual voltage behavior; and changing, in the adjustment, the parameter so as to simulate a state transition of the energy storage device model accompanied by the flow of the model current.

Hereinafter, the present disclosure will be specifically described with reference to the drawings showing embodiments thereof.

### First Embodiment

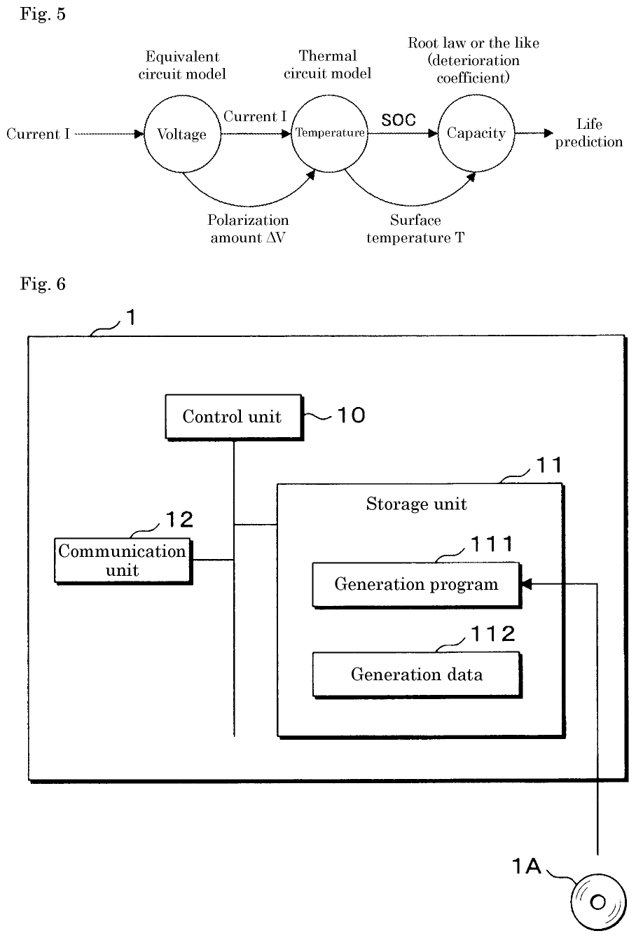

FIG. 5 is a conceptual diagram showing an overall image of life prediction calculation of the energy storage device. First, the overall image of the life prediction calculation and the positioning of the ECM will be described with reference to FIG. 5.

When an energy storage system is designed, life prediction calculation of an energy storage device is generally performed. FIG. 5 schematically shows calculation of how much the full charge capacity of the initial energy storage device will decrease (deteriorate) after 10 years. In a first step of the life prediction calculation, an ECM that outputs a transient voltage behavior of the energy storage device when a current flowing through the energy storage device is input is used.

In a second step of the life prediction calculation, a thermal circuit model that outputs the temperature of the energy storage device based on the current and the voltage is used. In a third step of the life prediction calculation, the deterioration amount of the energy storage device is calculated by a method such as a root law or a linear law based on the voltage behavior obtained in the first step and the temperature change obtained in the second step. The life of the energy storage device is predicted based on the obtained deterioration amount. By repeating the first step to the third step, how much the energy storage device deteriorates after 10 years is calculated. As described above, since the ECM is used in the first step of the life prediction calculation, the accuracy of the life prediction of the final energy storage device can be improved by improving the estimation accuracy in the ECM.

In the present embodiment, an ECM capable of appropriately simulating the voltage behavior of the energy storage device is generated by adjusting parameters to be described later.

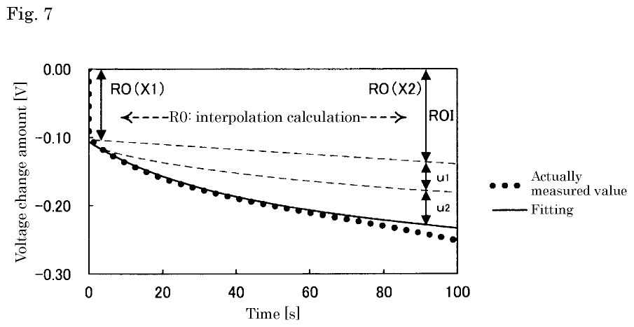

FIG. 6 is a block diagram of a generation device 1 according to the present embodiment. The generation device 1 includes a control unit 10, a storage unit 11, and a communication unit 12.

The control unit 10 is an arithmetic circuit including a central processing unit (CPU), a read only memory (ROM), a random access memory (RAM), and the like. The CPU included in the control unit 10 executes various computer programs stored in the ROM or the storage unit 11 and controls the operation of each unit of the hardware described above, thereby causing the entire device to function as the generation device of the present disclosure. The control unit 10 may have functions such as a timer that measures an elapsed time from when a measurement start instruction is given to when a measurement end instruction is given, a counter that counts the number, and a clock that outputs date and time information.

The storage unit 11 is a storage device such as a hard disk or a solid state drive (SSD). The storage unit 11 stores various computer programs and data. The computer program stored in the storage unit 11 includes a generation program 111 for generating the energy storage device model ECM. The data stored in the storage unit 11 includes generation data 112 used for generating the energy storage device model ECM. The generation data 112 may include actually measured data for generating the energy storage device model ECM to be generated, configuration information indicating a circuit configuration of the energy storage device model ECM, and the like.

The computer program (computer program product) stored in the storage unit 11 may be provided by a non-transitory recording medium 1A on which the computer program is recorded in a readable manner. The recording medium 1A is a portable memory such as a CD-ROM, a USB memory, or a secure digital (SD) card. The control unit 10 reads a desired computer program from the recording medium 1A using a reading device (not shown), and stores the read computer program in the storage unit 11. Alternatively, the computer program may be provided by communication. The generation program 111 can be deployed to execute on a single computer or on multiple computers located at one site or distributed across multiple sites and interconnected by a communication network.

The communication unit 12 is a communication interface for communicating with an external device. The external device is a terminal device such as a personal computer or a smartphone used by a user, an administrator, or the like. The control unit 10 transmits the information on the generated energy storage device model ECM from the communication unit 12 to the external device. The external device receives the information transmitted from the communication unit 12, and executes various simulations using the energy storage device model ECM based on the received information.

The generation device 1 may include an input unit that receives other operation inputs, a display unit that displays an image, and the like.

FIG. 7 is an explanatory diagram for explaining a method for acquiring circuit parameters in the energy storage device model ECM of the present embodiment. Hereinafter, an example of obtaining a circuit parameter of the ECM simulating a transient voltage behavior of the energy storage device when the discharge current flows for a predetermined period from the discharge start time point to the discharge end time point will be described. The calculation interval is every 1 second. The graph in FIG. 7 shows the relationship between the discharge time and the voltage change as in FIG. 3. The horizontal axis of the graph represents the time (s) from the start of discharge, and the vertical axis represents the voltage change amount ΔV (V) due to the internal impedance obtained by subtracting the change in the open circuit voltage due to the change in SOC from the voltage change amount accompanying discharge. A dot in FIG. 7 represents a voltage change amount obtained by actual measurement, and a solid line represents a voltage change amount obtained by fitting calculation described later.

The actually measured voltage change amount may be obtained, for example, by measuring a voltage of the energy storage device when discharging is performed at a predetermined SOC interval (for example, every 10%) from full charge (SOC 100%) by a constant current discharge test, and subtracting an OCV acquired in advance from the measured voltage.

The SOC of the ECM at the discharge start time point is X1%, and the SOC of the ECM at the discharge end time point is X2%. In the case of discharging every SOC 10% in the constant current discharge test, X2=X1−10 may be satisfied.

As described above, in the conventional method, fitting calculation is performed by preparing five circuit parameters R0, R1, C1, R2, and C2. In the present embodiment, ten circuit parameters of R0 (X1), R1 (X1), C1 (X1), R2 (X1), and C2 (X1) corresponding to the SOC value X1 of the energy storage device and R0 (X2), R1 (X2), C1 (X2), R2 (X2), and C2 (X2) corresponding to the SOC value X2 of the energy storage device are acquired as the elements constituting the ECM.

First, an initial (1 second from the start time point) voltage drop value obtained from the actually measured data is divided by an energized current value to set R0 (X1). R0 of the SOC value Xe % calculated based on R0 (X1) is set to R0 (X2) with reference to the correlation between R0 and the SOC.

Based on R0 (X1) and R0 (X2), the voltage behavior after 1 second elapses is obtained by fitting calculation. The remaining eight parameters R1 (X1), C1 (X1), R2 (X1), C2 (X1), R1 (X2), C1 (X2), R2 (X2), and C2 (X2) are calculated by fitting calculation by adjusting the voltage behavior of the ECM to approach the profile connecting the dots. In this case, R0 corresponding to the SOC value after 1 second elapses is calculated by performing interpolation calculation using R0 (X1) and R0 (X2), and fitting calculation of eight circuit parameters is performed using R0 thus calculated.

Optimization calculation may be used to adjust the circuit parameters. As the optimization calculation, for example, a nonlinear programming method may be used. Specifically, the circuit parameters may be adjusted using a method such as generalized reduced gradient descent (GRG) or a genetic algorithm. R0 (X1), R1 (X1), C1 (X1), R2 (X1), and C2 (X1) thus obtained are recorded in the two-dimensional table data in association with the SOC value X1 and the temperature at the start time point. R0 (X2), R1 (X2), C1 (X2), R2 (X2), and C2 (X2) are recorded in the two-dimensional table data in association with the SOC value X2 and the temperature at the end time point.

In the same procedure, circuit parameters for the next period (period corresponding to a SOC value X3 from the SOC value X2 of the energy storage device) are acquired. In the case of discharging every SOC 10% in the constant current discharge test, X3=X2−10 may be satisfied. An SOC value at a start time point of the predetermined period is set to X2, an SOC value at an end time point is set to X3, and each circuit parameter is determined by fitting. In this case, R0 (X3) is determined based on the voltage drop value obtained from the actually measured data. R0 (X2), R1 (X2), C1 (X2), R2 (X2), and C2 (X2) have already been acquired. Therefore, based on these six circuit parameters, the remaining four circuit parameters R1 (X3), C1 (X3), R2 (X3), and C2 (X3) may be calculated by fitting calculation. In this way, circuit parameters corresponding to the respective SOC values are sequentially obtained.

According to the above method, in order to simulate the transient actual voltage behavior (actually measured data) when the actual current is caused to flow in the actual energy storage device for a predetermined period, it is possible to obtain the circuit parameter in which the transient model voltage behavior when the model current equivalent to the actual current is caused to flow in the energy storage device model ECM including the parameter for a predetermined period is adjusted so as to approach the actual voltage behavior.

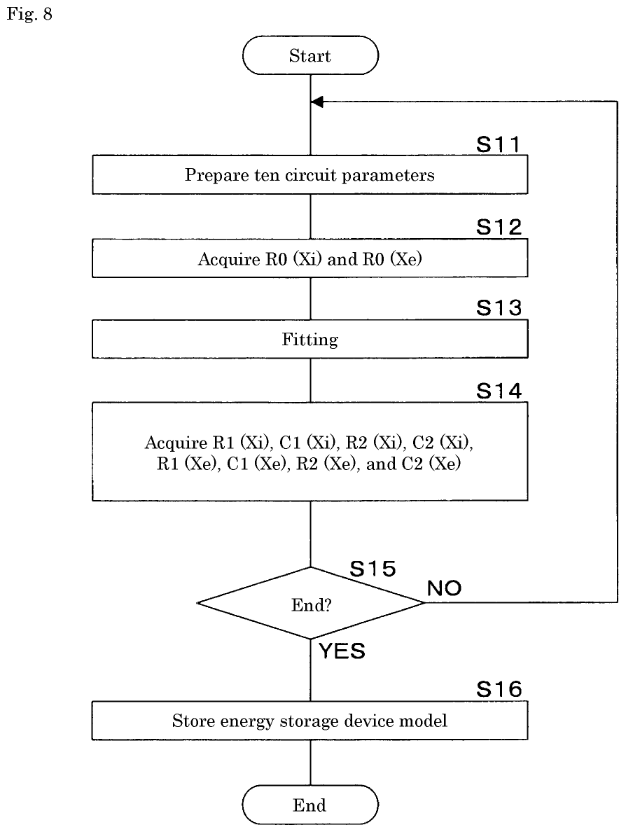

FIG. 8 is a flowchart showing an example of a generation processing procedure of the energy storage device model ECM. The control unit 10 of the generation device 1 executes the following processing according to the generation program 111. Hereinafter, as the energy storage device model ECM, an ECM including a resistor that simulates a DC resistance component of the energy storage device, a first RC parallel circuit that simulates first polarization characteristics of the energy storage device, and a second RC parallel circuit that simulates second polarization characteristics of the energy storage device is generated.

The control unit 10 of the generation device 1 refers to the generation data 112 of the storage unit 11 to acquire configuration information, actually measured data, and the like of the ECM to be generated, and prepares ten circuit parameters in the ECM (step S11). The circuit parameters include R0 (Xi), R1 (Xi), C1 (Xi), R2 (Xi), and C2 (Xi) corresponding to the SOC value Xi % at the start time point of the predetermined period to be calculated, and R0 (Xe), R1 (Xe), C1 (Xe), R2 (Xe), and C2 (Xe) corresponding to the SOC value Xe % at the end time point of the predetermined period.

The control unit 10 acquires R0 (Xi) and R0 (Xe) (step S12). Specifically, the control unit 10 acquires R0 (Xi) by calculating a voltage drop value in less than 1 second to 1 second from the start time point based on the actually measured data. The control unit 10 acquires R0 (Xe) corresponding to the SOC value Xe % based on the correlation between R0 and the SOC.

The control unit 10 performs fitting calculation based on R0 (Xi) and R0 (Xe) such that the voltage behavior after 1 second elapses follows the actually measured data (step S13). In this case, the control unit 10 calculates R0 corresponding to the SOC value after 1 second elapses has elapsed by performing interpolation calculation using R0 (Xi) and R0 (Xe), and performs fitting calculation of eight circuit parameters based on R0 thus calculated which corresponds to the SOC value after 1 second elapses has elapsed. The control unit 10 may adjust the circuit parameters by using a method such as generalized reduced gradient descent (GRG) or a genetic algorithm.

The control unit 10 acquires circuit parameters R1 (Xi), C1 (Xi), R2 (Xi), C2 (Xi), R1 (Xe), C1 (Xe), R2 (Xe), and C2 (Xe) according to the fitting (step S14).

The control unit 10 determines whether or not to end the processing (step S15). For example, when the circuit parameters are acquired for all the predetermined periods (SOC values), the control unit 10 determines that the processing is ended. When determining not to end the processing (step S15: NO), the control unit 10 returns the processing to step S11 and repeats acquisition of the circuit parameters in the next period.

When acquiring the circuit parameters in the next period, the control unit 10 may use R1 (Xe), C1 (Xe), R2 (Xe), and C2 (Xe) already acquired. The control unit 10 sets five circuit parameters corresponding to the SOC value at the end time point in the previous period as circuit parameters corresponding to the SOC value at the start time point in the next period. The control unit 10 also sets R0 (Xe) at the end time point in the next period according to the actually measured data. The control unit 10 performs fitting calculation based on the set six circuit parameters, and acquires R1 (Xe), C1 (Xe), R2 (Xe), and C2 (Xe) at the end time point in the next period.

When it is determined to end the processing (step S15: YES), the control unit 10 stores the configuration information of the ECM, the two-dimensional table including each circuit parameter, and the like in the storage unit 11 (step S16), and ends the series of processing. The control unit 10 may transmit the information on the generated ECM to an external device or the like via the communication unit 12.

In the above-described processing, the control unit 10 may determine the estimation accuracy of the generated ECM. The control unit 10 calculates a voltage response to the model current using the ECM including each acquired circuit parameter, and determines whether or not an error between the obtained voltage response and the actually measured data is less than a preset threshold value. When the error is not less than the threshold value, the control unit 10 may perform the processing in and after step S12 again and readjust the circuit parameter.

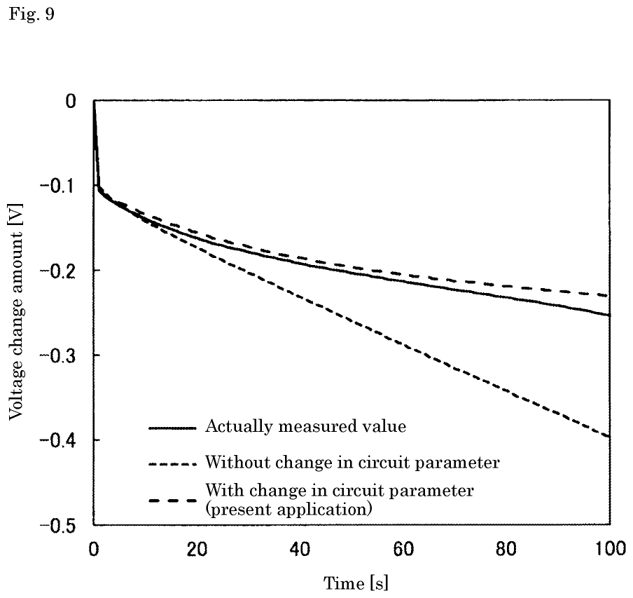

FIG. 9 is a graph showing a verification result of the ECM generated by the method of the present embodiment. The horizontal axis of the graph shown in FIG. 9 represents a time (s) from the start of discharge, and the vertical axis represents a voltage change amount ΔV (V) accompanying discharge. The simulation conditions are an environmental temperature of the energy storage device of 10° C., a discharge start SOC of 20%, and a discharge time of 100 seconds. For reference, the graph of the actually measured values and the reproduction result of the conventional ECM are shown together in FIG. 9. As compared with the case where the circuit parameter is changed in consideration of the fluctuation of the SOC (present technique) and the case where the circuit parameter is not changed (conventional technique), the actual measurement reproduction accuracy can be enhanced. Here, the error average is used as a parameter reflecting the reproduction accuracy. The error average is defined as Σ{(actually measured voltage)−(calculated voltage)}/(number of data points). The error average of the voltage change amount between the reproduction result by the conventional ECM and the actually measured value is 73.9 mV, whereas the error average of the voltage change amount between the reproduction result by the ECM of the present application and the actually measured value is −9.6 mV.

According to the present embodiment, by adjusting the circuit parameter in consideration of the fluctuation of the SOC in the energy storage device, the ECM can be generated in consideration of the SOC dependency of the circuit parameter. When calculating the current-voltage response in the case of discharging from the SOC 20% to the SOC 30%, for example, using the ECM, the circuit parameter at the middle time point of the discharge period is estimated by interpolation calculation from the circuit parameters of the SOC 20% and the SOC 30%. Since the circuit parameters are adjusted in consideration of SOC dependency (on the premise that the circuit parameters to be used at the time of calculation are made different as the SOC of the energy storage device changes from 20% to 30%), the reproduction accuracy at the time of calculating the current-voltage response can be improved.

### Second Embodiment

In the second embodiment, in addition to the circuit parameter R0 related to the DC resistance component, the circuit parameters R1 and R2 related to the RC parallel circuit are changed. Hereinafter, differences from the first embodiment will be mainly described, and configurations common to the first embodiment will be denoted by the same reference numerals, and a detailed description thereof will be omitted.

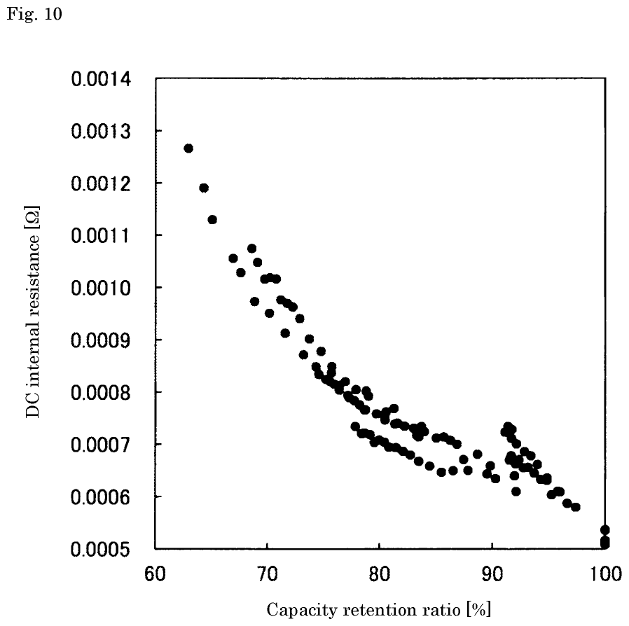

Conventionally, it has been known that there is a correlation between a DC internal resistance (DCR) and a capacity retention ratio (SOH) of an energy storage device. FIG. 10 is a graph showing the relationship between the DC internal resistance and the capacity retention ratio of the lithium ion battery. In the graph shown in FIG. 10, the horizontal axis represents the capacity retention ratio SOH (%), and the vertical axis represents the DC internal resistance DCR (ohmic resistance from less than 1 second to 1 second when calculated at intervals of 1 second, unit: Ω). The capacity retention ratio corresponds to a health state of the energy storage device. As shown in FIG. 10, the DCR increases as the SOH decreases. When the correlation between the SOH and the DCR is functionalized, Expression (3) below is established.

$$Δ R = ( SOH , T ) \qquad ( 3 )$$

Here, ΔR is a resistance deterioration amount of the energy storage device.

Conventionally, a method has been used in which deterioration of an energy storage device is ignored and a circuit parameter of an ECM is not changed after once determined. Here, a method for adding a resistance deterioration amount to the circuit parameter R0 related to the DC resistance component in the ECM shown in FIG. 1 can be used in order to simulate the state transition of the battery called deterioration. The voltage behavior in the ECM by this method can be expressed by Expressions (4) and (5) below.

$$[ Expression 2 ]$$

$${V}_{calc} = {V}_{ocv} + R {0}^{′} I + {u}_{1} + {u}_{2} \qquad ( 4 )$$

$$R {0}^{′} = {R}_{0} + Δ R = ( SOH , T ) \qquad ( 5 )$$

In the ECM described above, the deterioration in the RC parallel circuit is not considered. When the relational expressions (4) and (5) are used, only R0′ changes as the energy storage device deteriorates, so that the expression performance in the RC parallel circuit expressing the nonlinear polarization curve deteriorates. In the present embodiment, the circuit parameters R1 and R2 related to the RC parallel circuit are changed in addition to R0′ in order to more appropriately express the polarization behavior in consideration of deterioration with time change.

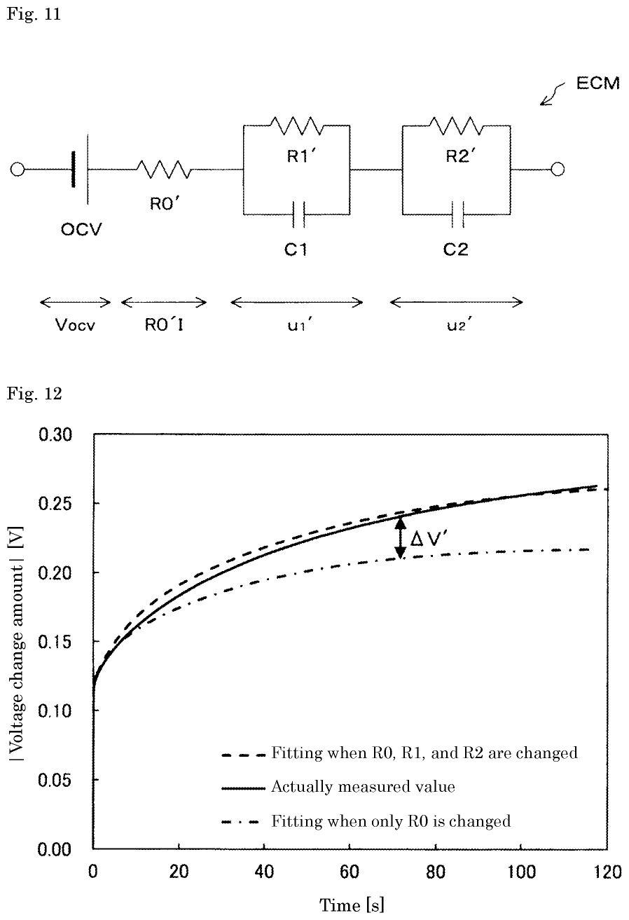

FIG. 11 is a diagram showing an example of an ECM of an energy storage device in the second embodiment. The ECM includes, as circuit parameters, an OCV that simulates a battery, and an R0′ and two stages of RC parallel circuits (R1′, C1, R2′, C2) that simulate overvoltage. The voltage behavior in the ECM shown in FIG. 11 can be expressed by Expressions (6) to (8) below.

$$[ Expression 3 ]$$

$${V}_{calc} = {V}_{ocv} + R {0}^{′} I + {u}_{1}^{′} + {u}_{2}^{′} \qquad ( 6 )$$

$${u}_{n ( t )}^{′} = ( 1 - \frac{Δ t}{{R}_{n}^{′} {C}_{n}} ) {u}_{n ( t )}^{′} + \frac{Δ t}{{C}_{n}} I \qquad ( 7 )$$

$${R}_{n}^{′} = {R}_{n} + {k}_{n} ( T ) * Δ R = ( SOH , T ) \qquad ( 8 )$$

Here, Vcalc is a model voltage (terminal voltage), un′ is a voltage change amount by an RC parallel circuit including Rn′ and Cn, and kn (T) is a correction coefficient having temperature dependency. Hereinafter, kn (T) is simply referred to as kn for simplicity.

FIG. 12 is an explanatory diagram for explaining a method for acquiring circuit parameters in the energy storage device model ECM of the second embodiment. The horizontal axis of the graph shown in FIG. 12 represents a time (s) from the start of discharge, and the vertical axis represents an absolute value of the voltage change amount ΔV (V) accompanying discharge. In FIG. 12, a solid line represents an actually measured value, a broken line represents a fitting result by the ECM of the present embodiment, and an alternate long and short dash line represents a fitting result by the conventional ECM.

As shown in FIG. 12, in the conventional method for changing only R0, a deviation from the actually measured value occurs. In the present embodiment, the deviation ΔV′ (difference between the value by the conventional method and the actually measured value) is expressed by R1′ and R2′.

Using the circuit parameters R0, R1, C1, R2, and C2 in the conventional ECM expressed by Expressions (4) and (5), the generation device 1 obtains R0′, R1′, and R2′ in consideration of deterioration. The generation device 1 acquires each circuit parameter in the conventional ECM in advance, and stores a two-dimensional table of each acquired circuit parameter in the generation data 112.

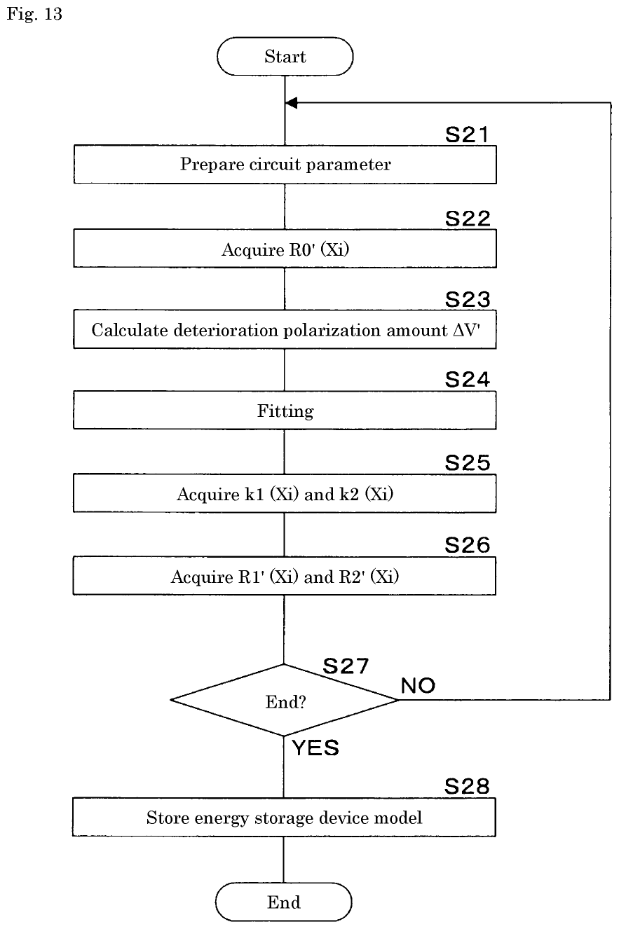

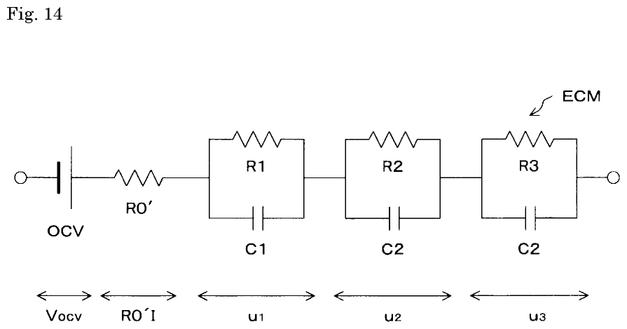

FIG. 13 is a flowchart showing an example of a generation processing procedure of the energy storage device model ECM in the second embodiment. The control unit 10 of the generation device 1 executes the following processing according to the generation program 111.

The control unit 10 of the generation device 1 refers to the generation data 112 in the storage unit 11 to acquire the configuration information of the ECM to be generated, the circuit parameters R0 (Xi), R1 (Xi), C1 (Xi), R2 (Xi), and C2 (Xi), actually measured data, and the like in the conventional ECM, and prepares the circuit parameters in the ECM (step S21). The circuit parameters include R0′ (Xi), R1′ (Xi), C1 (Xi), R2′ (Xi), C2 (Xi), k1 (Xi), and k2 (Xi) corresponding to the SOC value Xi % at the start time point of the predetermined period to be calculated.

The control unit 10 acquires a value obtained by adding the resistance deterioration amount ΔR (SOH, T) determined from the SOC value and the temperature at the start time point to R0 (Xi) as R0′ (Xi) (step S22). The control unit 10 calculates a deterioration polarization amount ΔV′ at each time point from the start time point to the end time point of the predetermined period using the following relational expression (9) (step S23).

$$Δ {V}^{′} = ΔV - ΔV calc \qquad ( 9 )$$

Here, ΔV is a polarization amount (a voltage change amount accompanying discharge), and AVcalc is a calculated value of the polarization amount obtained by Expressions (4) and (5) described above. AV′ means a difference between the actually measured value and the calculated value when only R0 (Xi) is changed.

The control unit 10 performs fitting calculation such that the deterioration polarization amount after 1 second elapses follows ΔV′ thus calculated (step S24), and acquires k1 (Xi) and k2 (Xi) (step S25). Specifically, the control unit 10 adjusts k1 (Xi) and k2 (Xi) such that a value obtained by adding k1 (Xi)×ΔR (SOH, T) and k2 (Xi)×ΔR (SOH, T) follows ΔV′.

The control unit 10 acquires R1′ (Xi) and R2′ (Xi) based on k1 (Xi) and k2 (Xi) thus acquired (step S26). Specifically, the control unit 10 calculates R1′ (Xi) by substituting R1 (Xi), k1 (Xi), and ΔR (SOH, T) into Expression (8) and executing the arithmetic processing of Expression (8). Similarly, R2′ (Xi) is calculated based on R2 (Xi), k2 (Xi), and ΔR (SOH, T).

The control unit 10 determines whether or not to end the processing (step S27). For example, when the circuit parameters are acquired for all the predetermined periods (SOC values), the control unit 10 determines that the processing is ended. When determining not to end the processing (step S27: NO), the control unit 10 returns the processing to step S21 and repeats acquisition of the circuit parameters in the next period.

When it is determined to end the processing (step S27: YES), the control unit 10 stores the configuration information of the ECM, the two-dimensional table including various circuit parameters, and the like in the storage unit 11 (step S28), and ends the series of processing.

In the above-described processing, the control unit 10 may determine whether or not k1 (Xi) and k2 (Xi) thus acquired have temperature dependency. When the correlation between the temperature of the energy storage device and each of k1 (Xi) and k2 (Xi) does not satisfy the predetermined condition, the control unit 10 may perform the processing in and after step S24 again to readjust k1 (Xi) and k2 (Xi).

According to the present embodiment, the ECM reflecting the change in the resistance deterioration amount according to the health state and temperature of the ECM can be generated by the circuit parameters R1′ and R2′.

### Third Embodiment

In a third embodiment, a new RC parallel circuit is added to express resistance deterioration of the energy storage device. Hereinafter, differences from the first embodiment and the second embodiment will be mainly described, and configurations common to the first embodiment and the second embodiment will be denoted by the same reference numerals, and a detailed description thereof will be omitted.

FIG. 14 is a diagram showing an example of an ECM of an energy storage device in the third embodiment. The ECM includes, as circuit parameters, an OCV that simulates a battery, and R0′ and three stages of RC parallel circuits (R1, C1, R2, C2, R3, C3) that simulate overvoltage. The voltage behavior in the ECM shown in FIG. 14 can be expressed by Expressions (10) to (13) below.

$$[ Expression 4 ]$$

$${V}_{calc} = {V}_{ocv} + R {0}^{′} I + {u}_{1} + {u}_{2} + {u}_{3} \qquad ( 10 )$$

$${u}_{n ( t )} = ( 1 - \frac{Δ t}{{R}_{n} {C}_{n}} ) {u}_{n ( t - 1 )} + \frac{Δ t}{{C}_{n}} I \qquad ( 11 )$$

$${R}_{3} + {k}_{n} ( SOC , T ) * Δ R = ( SOH , T ) \qquad ( 12 )$$

$${C}_{3} = {C}_{3} ( SOH , T ) \qquad ( 13 )$$

Here, Vcalc is a model voltage (terminal voltage), un is a voltage change amount by an RC parallel circuit including Rn and Cn, and kn (SOC, T) is a correction coefficient having SOC and temperature dependency.

As shown in Expressions (10) to (13), R3 depends on an SOC, a temperature, and an SOH of the energy storage device. C3 and R3 depend on the SOC and the temperature of the energy storage device. Among the circuit parameters related to the three RC parallel circuits, the circuit parameters that change with the deterioration of the energy storage device are only R3 and C3 related to the newly added RC parallel circuit at the third stage. In the present embodiment, ΔV′ (the difference between the value by the conventional method and the actually measured value) shown in FIG. 12 is expressed by the RC parallel circuit including R3 and C3.

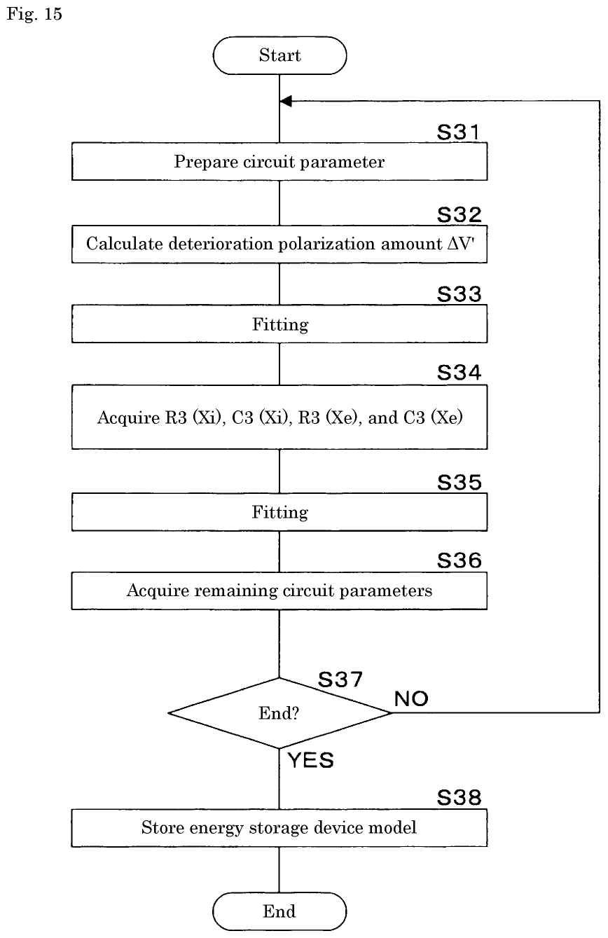

FIG. 15 is a flowchart showing an example of a generation processing procedure of the energy storage device model ECM in the third embodiment. The control unit 10 of the generation device 1 executes the following processing according to the generation program 111.

The control unit 10 of the generation device 1 refers to the generation data 112 of the storage unit 11 to acquire configuration information, actually measured data, and the like of the ECM to be generated, and prepares circuit parameters in the ECM (step S31). The circuit parameters include R0′ (Xi), R1 (Xi), C1 (Xi), R2 (Xi), C2 (Xi), R3 (Xi), and C3 (Xi) corresponding to the SOC value Xi % at the start time point of the predetermined period to be calculated, and R0′ (Xe), R1 (Xe), C1 (Xe), R2 (Xe), C2 (Xe), R3 (Xe), and C3 (Xe) corresponding to the SOC value Xe % at the end time point of the predetermined period.

The control unit 10 calculates the deterioration polarization amount ΔV′ at each time point from the start time point to the end time point of the predetermined period using Expression (9) above (step S32). AV′ means a difference between an actually measured value and a calculated value when an ECM that does not include the RC parallel circuit at the third stage (an RC parallel circuit including a circuit parameter that changes with deterioration) is used.

The control unit 10 performs fitting calculation such that the deterioration polarization amount after 1 second elapses follows ΔV′ thus calculated (step S33), and acquires R3 (Xi), C3 (Xi), R3 (Xe), and C3 (Xe) (step S34). Specifically, the control unit 10 adjusts the four circuit parameters such that a RC parallel circuit u3 at the third stage follows ΔV′.

The control unit 10 performs fitting calculation based on the four circuit parameters such that the voltage behavior after 1 second elapses has elapsed follows the actually measured data (step S35). In this case, the control unit 10 calculates R3 and C3 corresponding to the SOC value after 1 second elapses by performing interpolation calculation using the above four circuit parameters, and performs fitting calculation of the remaining circuit parameters using R3 and C3 thus calculated. The method for calculating the remaining circuit parameters may be similar to that of the first embodiment.

The control unit 10 acquires circuit parameters R0′ (Xi), R1 (Xi), C1 (Xi), R2 (Xi), C2 (Xi), R0′ (Xe), R1 (Xe), C1 (Xe), R2 (Xe), and C2 (Xe) according to the fitting (step S36).

The control unit 10 determines whether or not to end the processing (step S37). For example, when the circuit parameters are acquired for all the predetermined periods (SOC values), the control unit 10 determines that the processing is ended. When determining not to end the processing (step S37: NO), the control unit 10 returns the processing to step S31 and repeats acquisition of the circuit parameters in the next period.

When it is determined to end the processing (step S37: YES), the control unit 10 stores the configuration information of the ECM, the two-dimensional table including various circuit parameters, and the like in the storage unit 11 (step S38), and ends the series of processing.

According to the present embodiment, the ECM includes a new RC parallel circuit for expressing a change in the resistance deterioration amount according to the health state and temperature of the ECM. Since deterioration of the ECM can be expressed by the RC parallel circuit, man-hours can be reduced as compared with the case of changing the circuit parameters R1′ and R2′ in the second embodiment.

### Fourth Embodiment

In the fourth embodiment, circuit parameters in consideration of heat generation of an energy storage device are acquired. Hereinafter, differences from the first embodiment to the third embodiment will be mainly described, and configurations common to the first embodiment to the third embodiment will be denoted by the same reference numerals, and a detailed description thereof will be omitted. As in the third embodiment, the ECM in the fourth embodiment includes, as circuit parameters, an OCV that simulates a battery, and R0′ and three stages of RC parallel circuits (R1, C1, R2, C2, R3, C3) that simulate overvoltage.

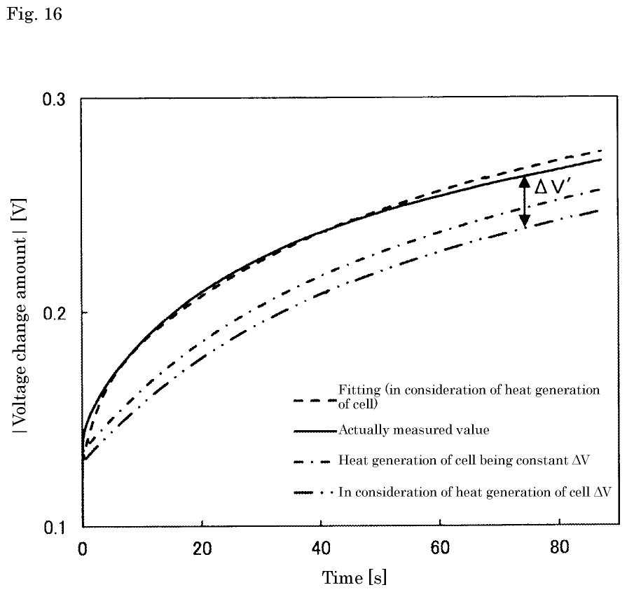

FIG. 16 is an explanatory diagram for explaining a method for acquiring circuit parameters in the energy storage device model ECM of the fourth embodiment. The horizontal axis of the graph shown in FIG. 16 represents a time (s) from the start of discharge, and the vertical axis represents an absolute value of the voltage change amount ΔV (V) accompanying discharge. In FIG. 16, a solid line indicates an actually measured value, a broken line indicates a fitting result by the ECM of the present embodiment, an alternate long and short dash line indicates a voltage behavior in a case where heat generation of the energy storage device is assumed to be constant, and an alternate long and two short dashes line indicates a voltage behavior in a case where heat generation of the energy storage device is considered.

As shown in FIG. 16, the voltage behavior in the case where a temperature change due to heat generation of the energy storage device is considered is different from the voltage behavior in the case where heat generation of the energy storage device is assumed to be constant. Therefore, in the case of acquiring the circuit parameters R3 and C3 by the method of the third embodiment, when the difference ΔV′ between the voltage change amount and the actually measured value by the conventional method is calculated, the voltage change amount in the case of considering the temperature change due to heat generation of the energy storage device is used, whereby the ECM reproduction accuracy is further improved.

For example, in the case of using the conventional ECM expressed by Expressions (3) and (4), the generation device 1 changes ΔR (SOH, T) according to the temperature of the energy storage device at each time point, and acquires the circuit parameter R0′ according to ΔR (SOH, T) at each time point. The generation device 1 sets a value obtained by dividing AVcalc thus obtained by ΔV as ΔV′. ΔV′ is expressed by the RC parallel circuit at the third stage.

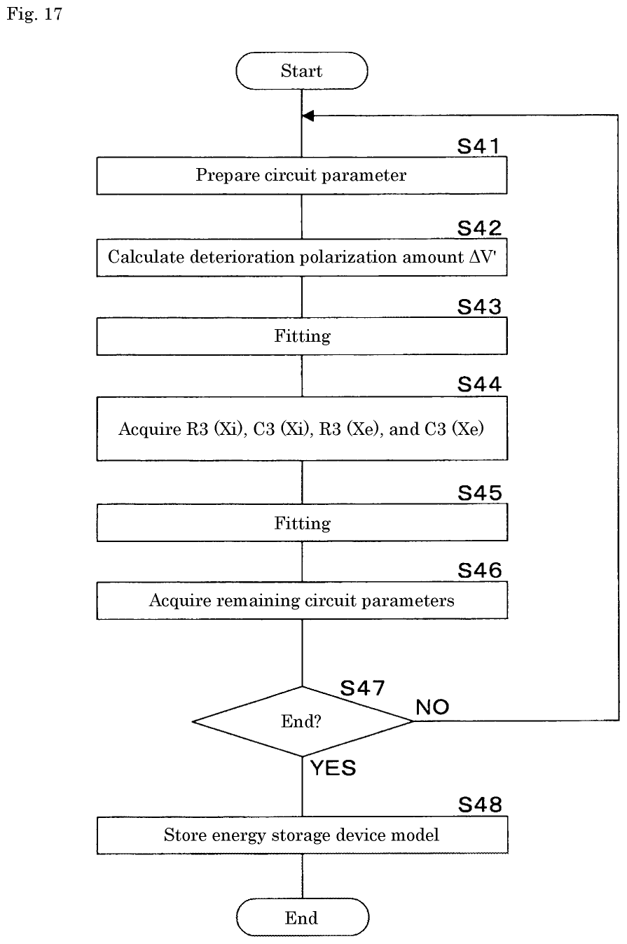

FIG. 17 is a flowchart showing an example of a generation processing procedure of the energy storage device model ECM in the fourth embodiment. The control unit 10 of the generation device 1 executes the following processing according to the generation program 111.

The control unit 10 of the generation device 1 refers to the generation data 112 of the storage unit 11 to acquire configuration information, actually measured data, and the like of the ECM to be generated, and prepares circuit parameters in the ECM (step S41). The circuit parameters include R0′ (Xi), R1 (Xi), C1 (Xi), R2 (Xi), C2 (Xi), R3 (Xi), and C3 (Xi) corresponding to the SOC value Xi % at the start time point of the predetermined period to be calculated, and R0′ (Xe), R1 (Xe), C1 (Xe), R2 (Xe), C2 (Xe), R3 (Xe), and C3 (Xe) corresponding to the SOC value Xe % at the end time point of the predetermined period.

The control unit 10 calculates the deterioration polarization amount ΔV′ at each time point from the start time point to the end time point of the predetermined period (step S42). In this case, the control unit 10 calculates ΔV′ in consideration of the temperature change of the energy storage device at each time point by using ΔR (SOH, T) in consideration of the temperature change due to the heat generation of the energy storage device at each time point. Thereafter, the generation device 1 performs generation processing of the energy storage device model ECM by executing processing similar to steps S33 to S38 shown in FIG. 15.

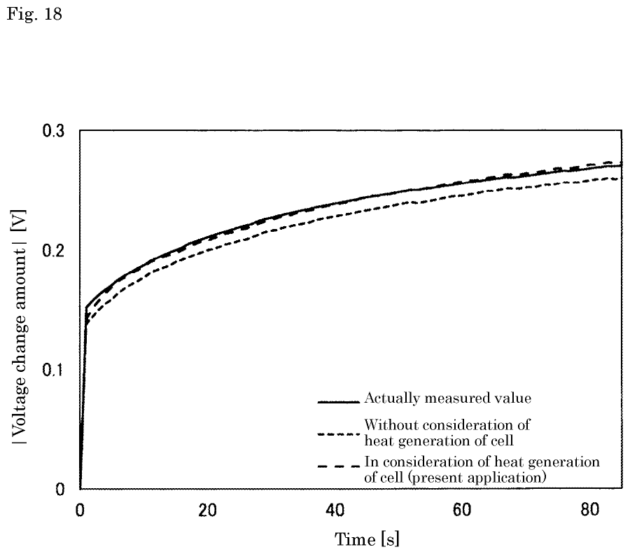

FIG. 18 is a graph showing a verification result of the ECM generated by the method of the fourth embodiment. The horizontal axis of the graph shown in FIG. 18 represents a time (s) from the start of discharge, and the vertical axis represents an absolute value of the voltage change amount ΔV (V) accompanying discharge. The simulation conditions are an environmental temperature of the energy storage device of 10° C., a discharge start SOC of 20%, and a discharge time of 85 seconds. For reference, the graph of the actually measured values and the reproduction result of the conventional ECM are shown together in FIG. 18. In the case where the circuit parameters R3 and C3 are calculated in consideration of the heat generation of the energy storage device (present application method), it is possible to enhance the actual measurement reproduction accuracy as compared with the case where the heat generation of the energy storage device is not considered (conventional method). The error average of the voltage change amount between the reproduction result by the conventional ECM and the actually measured value is −10.5 mV, whereas the error average of the voltage change amount between the reproduction result by the ECM of the present application and the actually measured value is −0.3 mV.

According to the present embodiment, the ECM makes it possible to simulate the current-voltage characteristics in consideration of the change in the resistance deterioration amount due to the heat generation of the energy storage device.

In the examples described in the above embodiments, other embodiments can be realized by combining all or some of the configurations described in the embodiments. In addition, the sequence described in each of the above embodiments is not limited, and each processing procedure may be executed in a changed order within a range in which there is no contradiction in processing contents, or a plurality of processes may be executed in parallel.

It should be understood that the embodiments disclosed herein are illustrative in all respects and are not restrictive. The technical features described in the examples can be combined with each other, and the scope of the present invention is intended to include all modifications within the scope of the claims and the scope equivalent to the claims.

### DESCRIPTION OF REFERENCE SIGNS

1: generation device
10: control unit
11: storage unit
12: communication unit
111: generation program
112: generation data
1A: recording medium

1. A generation method for an energy storage device model, comprising:
adjusting, so as to simulate a transient actual voltage behavior when an actual current flows in an actual energy storage device for a predetermined period, a parameter in an energy storage device model such that a transient model voltage behavior, which is a behavior when a model current equivalent to the actual current flows in the energy storage device model for a predetermined period, approaches the actual voltage behavior; and
changing, in the adjustment, the parameter so as to simulate a state transition of the energy storage device model accompanied by the flow of the model current.

2. The generation method for an energy storage device model according to claim 1, wherein in the adjustment, the parameter at a time point between a start time point and an end time point of the predetermined period is obtained by interpolation calculation.

3. The generation method for an energy storage device model according to claim 2, wherein
the energy storage device model is an equivalent circuit model including a resistor that simulates a DC resistance component of the energy storage device, and
in the adjustment, the parameter related to the resistor is changed.

4. The generation method for an energy storage device model according to claim 1, wherein in the adjustment, the parameter is changed so as to simulate a transition of a health state and/or a temperature of the energy storage device model accompanied by the flow of the model current.

5. The generation method for an energy storage device model according to claim 4, wherein
the energy storage device model is an equivalent circuit model including a resistor that simulates a DC resistance component of the energy storage device, and an RC parallel circuit that simulates polarization characteristics of the energy storage device, and
in the adjustment, the parameter related to the resistor and the parameter related to the RC parallel circuit are changed.

6. The generation method for an energy storage device model according to claim 4, wherein
the energy storage device model is an equivalent circuit model including a resistor that simulates a DC resistance component of the energy storage device, and a plurality of RC parallel circuits that simulate polarization characteristics of the energy storage device, and
in the adjustment, the parameter related to at least one RC parallel circuit among the plurality of RC parallel circuits is changed, the RC parallel circuit being configured to express a transition of a health state and/or a temperature of the energy storage device model.

7. The generation method for an energy storage device model according to claim 4, wherein in the adjustment, the parameter is changed based on a heat generation amount of the energy storage device model.

8. A generation device for an energy storage device model comprising an adjustment unit that adjusts, so as to simulate a transient actual voltage behavior when an actual current flows in an actual energy storage device for a predetermined period, a parameter in an energy storage device model such that a transient model voltage behavior, which is a behavior when a model current equivalent to the actual current flows in the energy storage device model for a predetermined period, approaches the actual voltage behavior,
wherein the adjustment unit changes, in the adjustment, the parameter so as to simulate a state transition of the energy storage device model accompanied by the flow of the model current.

9. A program for causing a computer to execute the processing of:
adjusting, so as to simulate a transient actual voltage behavior when an actual current flows in an actual energy storage device for a predetermined period, a parameter in an energy storage device model such that a transient model voltage behavior, which is a behavior when a model current equivalent to the actual current flows in the energy storage device model for a predetermined period, approaches the actual voltage behavior; and
changing, in the adjustment, the parameter so as to simulate a state transition of the energy storage device model accompanied by the flow of the model current.
